(19) United States
(12) Patent Application Publication
(10) Pub. No.: US 2016/0027361 A1
(43) Pub. Date: Jan. 28, 2016

(54) DISPLAY DEVICE AND DRIVING METHOD THEREOF, MANUFACTURING METHOD OF ARRAY SUBSTRATE

(71) Applicants: BOE TECHNOLOGY GROUP CO., LTD., Beijing (CN); BEIJING BOE DISPLAY TECHNOLOGY CO., LTD., Beijing (CN)

(72) Inventors: Yan LI, Beijing (CN); Hongshu ZHANG, Beijing (CN); Yanping LIAO, Beijing (CN); Daekeun YOON, Beijing (CN)

(21) Appl. No.: 14/429,458

(22) PCT Filed: Jun. 30, 2014
(86) PCT No.: PCT/CN2014/081200

§ 371 Date: Mar. 19, 2015

(30) Foreign Application Priority Data
Nov. 11, 2013 (CN) 201310557864.9

(51) Int. Cl. G09G 3/20; H01L 27/12

(52) U.S. Cl. CPC G09G 3/2003; H01L 27/1259; H01L 27/124

(57) ABSTRACT

A display device is provided, and the display device includes an array substrate including a display zone thin film transistor situated in a display zone; a driving device including a charging current acquiring device, which is used for acquiring a charging current of the display zone thin film transistor, and includes a detecting thin film transistor with the same construction as the display zone thin film transistor. A driving method and a manufacturing method of the array substrate are also provided.

### TECHNICAL FIELD

Embodiments of the present invention relate to a display device and driving method thereof, a manufacturing method of an array substrate.

### BACKGROUND

As compared with traditional cathode ray tube display devices, flat panel display devices have the merits of being light and thin, low driving signal, flicker-free, no dithering, long service life, and so on; and flat panel display devices are classified into active light-emitting display devices and passive light-emitting display devices. For example, Thin Film Transistor-Liquid Crystal Displays (TFT-LCDs) are a kind of passive light-emitting display devices. As they have the merits of stable picture, lifelike images, irradiation eliminating, space saving, energy consumption saving and so on, they have been widely applied to televisions, cell phones, display devices and other electronic products, and have played a leading role in the field of planar display.

A liquid crystal display device mainly includes a display panel and a backlight module for providing the display panel with a light source; and the display panel mainly includes a first substrate and a second substrate that are disposed oppositely. In general, the first substrate and the second substrate are an array substrate and a color filter substrate, respectively, and pixel units arranged in a matrix form are disposed on the array substrate. Each of the pixel units includes a thin film transistor, a storage capacitor, a pixel electrode, a common electrode, etc.; and a liquid crystal layer is provided between the array substrate and the color filter substrate. In addition to the liquid crystal display panel, drive circuit boards must be linked in the periphery of the liquid crystal display device, so as to provide control signals, driving signals and so on for picture display.

As for the thin film transistor in the display area of the liquid crystal display panel, it works under a negative bias voltage for long time, and so, along with the accumulation of working time, the threshold voltage of the thin film transistor becomes larger, and this causes the charging current output from a drain electrode of the thin film transistor to decrease. Or, as a result of process (e.g. film quality, film thickness, etc.) factors, charging current output from the drain electrode of the thin film transistor will also be affected, and this results in decreasing of the charging current. In case of an insufficient charging of the display panel, display brightness of the picture of the display device is degraded, and in severe cases, it may lead to undesirable display of the picture of the display device. Therefore, it is required that the scan voltage input to a gate electrode of the thin film transistor be adjusted according to the charging current output from the thin film transistor in the display area, so as to ensure that the charging current of the display device in the display area lies within a proper range. But, as regards how to obtain size of the charging current output from the thin film transistor in the display area, methods in the prior art are usually too complex and have higher costs.

### SUMMARY

According to an embodiment of the present invention, there is provided a display device, comprising:

an array substrate, including a display-zone thin film transistor situated in a display zone;

a driving device, including a charging current acquiring device, which is configured to acquire a charging current of the display-zone thin film transistor, and includes a detecting thin film transistor having the same construction as the display-zone thin film transistor.

According to another embodiment of the present invention, there is provided a driving method of the above display device, comprising:

acquiring a charging current of the display-zone thin film transistor at a specific data signal voltage by the charging current acquiring device;

comparing the acquired charging current value with a preset charging current value:

in case that the acquired charging current value is smaller than the preset charging current value, adjusting a scan signal voltage or data signal voltage by a timing controller and/or a driving circuit board.

According to still another embodiment of the present invention, there is provided a manufacturing method of an array substrate, comprising:

forming a display-zone thin film transistor and a detecting thin film transistor with the same construction as the display-zone thin film transistor.

With respect to the charging current acquiring device provided by embodiments of the invention, by means of providing a detecting thin film transistor with the same construction as the display-zone thin film transistor, and providing the detecting thin film transistor with the same scan signal as that for the display-zone thin film transistor, and, selecting for it such a data signal that has the same data signal voltage as that for the display zone thin film transistor, a charging current of the display panel is accurately reflected by using the detecting thin film transistor. Thus, a basis is provided for adjustment of the driving signals. Furthermore, the charging current acquiring device provided by the invention also has the traits of simple structure, being easy to implement, and so on.

### BRIEF DESCRIPTION OF THE DRAWINGS

In order to illustrate the technical solution of the embodiments of the invention more clearly, the drawings of the embodiments will be briefly described below; it is obvious that the drawings as described below are only related to some embodiments of the invention, but not limitative of the invention.

FIG. 1 is a structurally schematic view illustrating a charging current acquiring device in a first embodiment of the invention;

FIG. 2 is a schematic view illustrating partial structure of a driving device of a display device in a second embodiment of the invention;

FIG. 3 is a schematic view illustrating partial structure of another driving device of a display device in the second embodiment of the invention;

FIG. 4 is a schematically flowchart illustrating a manufacturing method of an array substrate in a third embodiment of the invention.

### DETAILED DESCRIPTION

In order to make objects, technical details and advantages of the embodiments of the invention apparent, hereinafter, the technical solutions of the embodiments of the invention will be described in a clearly and fully understandable way in connection with the drawings related to the embodiments of the invention. It is obvious that the described embodiments are just a part but not all of the embodiments of the invention. Based on the described embodiments of the invention, those ordinarily skilled in the art can obtain other embodiment(s), without any inventive work, which should be within the scope sought for protection by the invention.

### First Embodiment

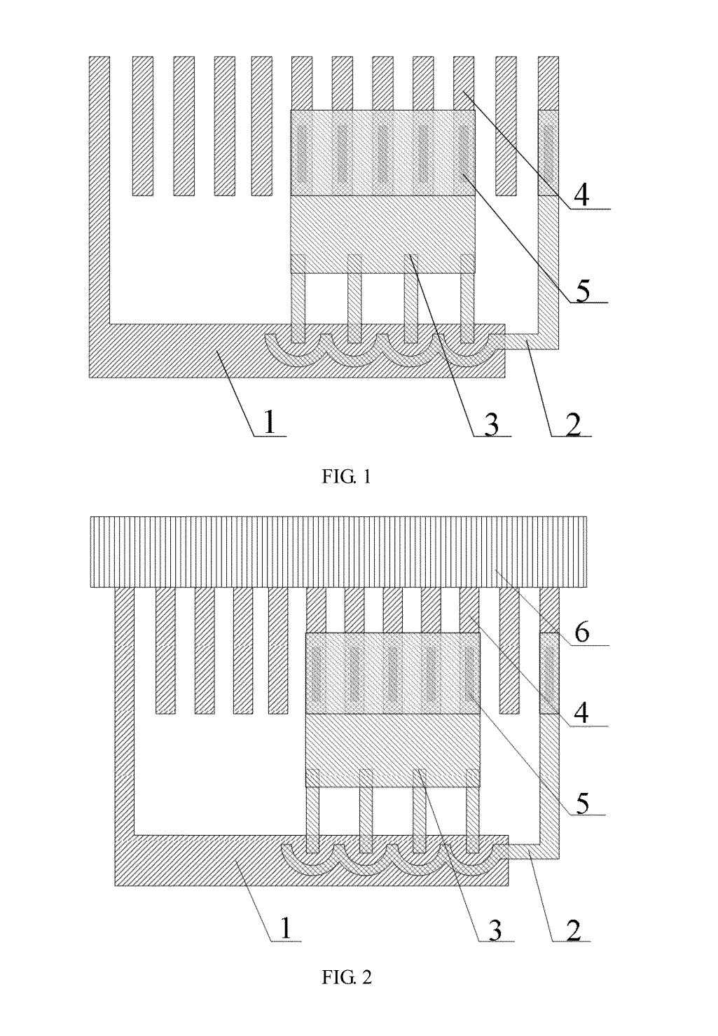

In the embodiment, there is provided a charging current acquiring device being configured for acquiring a charging current of a display-zone thin film transistor of a display device. The charging current acquiring device may be such as a thin film transistor for detection, and its structure may be preferably the same as a thin film transistor within a display region, and may also be made to be other structure or shape according to the requirements of the wiring areas. The number of a detecting thin film transistor may be one or more, and no special limitation will be made here. The detecting thin film transistor, as illustrated in FIG. 1, includes a gate electrode 1, a source electrode 2, a drain electrode 3, a gate insulating layer and an active layer (which are not illustrated in the figure).

A first scan signal is input to a gate electrode of the display-zone thin film transistor, a first data signal is input to its source electrode, and a charging current is output from its drain electrode to a storage capacitor and a pixel electrode. In order to accurately reflect the charging current of the display-zone thin film transistor, a second scan signal being the same as the above first scan signal is input to the gate electrode 1 of the detecting thin film transistor, that is, the second scan signal and the first scan signal have exactly the same voltage value and timing; a second data signal being the same as the above first data signal may be input to the source electrode 2 of the detecting thin film transistor, that is, the second data signal and the first data signal have exactly the same voltage value and timing. The acquired charging current is output from the drain electrode 3 of the detecting thin film transistor, and it can timely reflect the situation of the charging current of the current display zone thin film transistor. Alternatively, a data signal in correspondence with the display-zone thin film transistor at a specified gray scale may also be input to the source electrode 2 of the detecting thin film transistor, and the acquired charging current capable of reflecting the situation of the charging current at the specified gray level of the display-zone thin film transistor is output from the drain electrode 3 of the detecting thin film transistor. For example, a data signal in correspondence with the display-zone thin film transistor at the highest gray level, namely, in case there is a highest requirement on the charging current, is input to the source electrode 2 of the detecting thin film transistor, and the acquired charging current capable of reflecting the situation of the charging current of the display-zone thin film transistor under the highest charging requirements is output from the drain electrode 3 of the detecting thin film transistor.

The detecting thin film transistor in embodiments of the invention can be set at arbitrary location where detection is conducted conveniently, and for example, it may be arranged in an edge region of the display zone of the array substrate, or on a driving circuit board. Preferably, it is arranged on the array substrate, and for example, it is arranged in the vicinity of a wiring region or a pad region. For facilitating the production, the structure and shape of the detecting thin film transistor may be the same as those of the display zone thin film transistor, so as to facilitate formation of the detecting thin film transistor at the same time that the display zone thin film transistor is formed. Thus, uniformity of construction of the detecting thin film transistor and the display zone thin film transistor is assured.

Generally, the display device further includes a timing controller and driving circuit boards connected to the timing controller, the driving circuit boards acting to provide the display zone thin film transistor with scan signals, data signals and so on necessary for picture display, and the timing controller acting to provide the driving circuit boards with clock signals and control signals. A driving circuit board may be connected to wirings on the array substrate through a flexible circuit board, and may also be directly formed on the array substrate, so as to reduce the process cost of the display device, raise the integrated level of display device, etc.

When a driving circuit board is connected to the array substrate through a flexible circuit board, as illustrated in FIG. 2, the gate electrode 1, the source electrode 2 and the drain electrode 3 of the detecting thin film transistor may be connected to the flexible circuit board 6 through connecting lines 4, respectively, and the timing controller and the driving circuit board provide the gate electrode 1 of the detecting thin film transistor with a desired second scan signal via the flexible circuit board 6, and provide the source electrode 2 of the detecting thin film transistor with a second data signal. Moreover, the acquired charging current is transferred from the drain electrode 3 of the detecting thin film transistor to the driving circuit board and the timing controller via the flexible circuit board 6 by means of feedback.

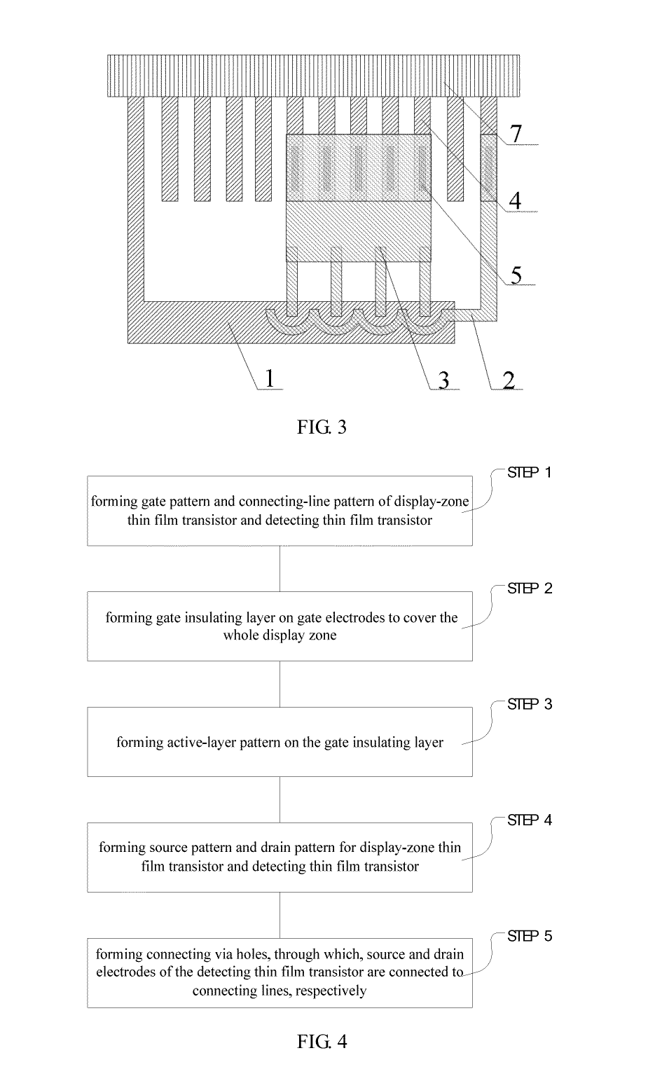

When a driving circuit board is directly formed on the array substrate, as illustrated in FIG. 3, the gate electrode 1, the source electrode 2 and the drain electrode 3 of the detecting thin film transistor may be connected to the driving circuit board 7 through connecting lines 4, respectively, and the timing controller and the driving circuit board 7 provide the gate electrode 1 of the detecting thin film transistor with a desired second scan signal, and provide the source electrode 2 of the detecting thin film transistor with a second data signal. Moreover, the acquired charging current is transferred from the drain electrode 3 of the detecting thin film transistor to the driving circuit board 7 and the timing controller by means of feedback.

### Second Embodiment

In the embodiment, there are provided a display device driving device and a driving method to which the charging current acquiring device provided in the second embodiment is applied.

The display device driving device in the embodiment includes the charging current acquiring device provided in the first embodiment, and includes a timing controller and a driving circuit board connected to the stated timing controller and so on besides. The driving circuit board provides a display zone thin film transistor with scan signals, data signals and so on necessary for picture display, and the timing controller acts to provide the driving circuit board with clock signals and control signals.

When a driving circuit board is connected to the array substrate through a flexible circuit board, as illustrated in FIG. 2, the gate electrode 1, the source electrode 2 and the drain electrode 3 of the detecting thin film transistor may be connected to the flexible circuit board 6 through connecting lines 4, respectively, and the timing controller and the driving circuit board provide the gate electrode 1 of the detecting thin film transistor with a desired second scan signal via the flexible circuit board 6, and provide the source electrode 2 of the detecting thin film transistor with a second data signal. Moreover, the acquired charging current is transferred from the drain electrode 3 of the detecting thin film transistor to the driving circuit board and the timing controller via the flexible circuit board 6 by means of feedback.

When a driving circuit board is directly formed on the array substrate, as illustrated in FIG. 3, the gate electrode 1, the source electrode 2 and the drain electrode 3 of the detecting thin film transistor may be connected to the driving circuit board 7 through connecting lines 4, respectively, and the timing controller and the driving circuit board 7 provide the gate electrode 1 of the detecting thin film transistor with a desired second scan signal, and provide the source electrode 2 of the detecting thin film transistor with a second data signal. Moreover, the acquired charging current is transferred from the drain electrode 3 of the detecting thin film transistor to the driving circuit board 7 and the timing controller by means of feedback.

The driving method of the display device in the embodiment mainly includes acquiring a charging current of the current display zone thin film transistor at a specific data signal voltage by the above charging current acquiring device, so as to adjust a scan signal voltage or a data signal voltage provided for the display zone thin film transistor in accordance with the acquired charging current. For example, after the charging current acquired by the above charging current acquiring device is transferred to a drive circuit board and a timing controller by means of feedback, the driving circuit board or the timing controller compares the acquired charging current value with a preset charging current value, and if the acquired charging current value is smaller than the preset charging current value, then the scan signal voltage or the data signal voltage provided to the display zone thin film transistor is automatically adjusted by the timing controller or the driving circuit board. Thus, the display effect of the display device is improved pertinently.

### Third Embodiment

In the embodiment, there are provided an array substrate and a manufacturing method of the array substrate. The array substrate in the embodiment includes the charging current acquiring device provided in the first embodiment, that is, the detecting thin film transistor, connecting lines 4 pertinent to the detecting thin film transistor and so on that are stated in the first embodiment are formed on the array substrate. The manufacturing method of the array substrate in the embodiment differs from a traditional manufacturing method of an array substrate mainly in that, in addition to formation of the display zone thin film transistor, a detecting thin film transistor with the same construction as the display zone thin film transistor also needs to be formed. In order to guarantee the uniformity of construction of the detecting thin film transistor and the display zone thin film transistor and to simplify the process flow, in the embodiment, the detecting thin film transistor and the display zone thin film transistor are formed simultaneously.

As illustrated in FIG. 4, the manufacturing method of the array substrate in the embodiment further includes:

Step 1, through a patterning process, a pattern of gate electrodes for a display zone thin film transistor and a detecting thin film transistor and a pattern of connecting lines are formed on a base substrate;

Step 2, a gate insulating layer covering the whole base substrate is formed on the gate electrodes and the connecting lines;

Step 3, through a patterning process, a pattern of an active layer is formed on the gate insulating layer;

Step 4, through a patterning process, a pattern of a source electrode and a pattern of a drain electrode for the display zone thin film transistor and a pattern of a source electrode and a pattern of a drain electrode for the detecting thin film transistor are formed on the active layer;

Step 5, through a patterning process, connecting via holes 5 are formed over the connecting lines 4; and the source electrode and the drain electrode of the detecting thin film transistor are connected to the connecting line 4 through the via holes 5, respectively.

Of course, in the actual use, the implementing method may be changed by means of increasing or decreasing the number of patterning process, selecting different materials or material combinations, so as to implement the manufacturing method of the array substrate in the embodiment.

According to an embodiment of the invention, there is further provided a display device, including:

an array substrate, including a display zone thin film transistor situated in a display zone;

a driving device, including a charging current acquiring device, which is configured for acquiring a charging current of the display zone thin film transistor, and includes a detecting thin film transistor with the same construction as the display zone thin film transistor.

In an example, a first scan signal is input to a gate electrode of the display zone thin film transistor, and a first data signal is input to its source electrode; a second san signal being the same as the first scan signal is input to a gate electrode of the detecting thin film transistor, and a second data signal is input to its source electrode; the acquired charging current is output from a drain electrode of the detecting thin film transistor.

In an example, the second data signal is the same as the first data signal; or, the second data signal is the same as a data signal in correspondence with the display zone thin film transistor at a selected gray scale.

In an example, the selected gray scale is the highest display gray scale of the display device.

In an example, the charging current acquiring device is formed on the array substrate.

In an example, the driving device further includes a driving circuit board that is formed on the array substrate; and a gate electrode, a source electrode and a drain electrode of the detecting thin film transistor are connected to the driving circuit board through connecting lines, respectively.

In an example, the driving device further includes a driving circuit board that is connected to the array substrate via a flexible circuit board; and a gate electrode, a source electrode and a drain electrode of the detecting thin film transistor are connected to the flexible circuit board through connecting lines, respectively.

In an example, the driving device further includes a timing controller.

In an example, the charging current acquiring device is arranged in a peripheral zone of the array substrate surrounding the display zone.

According the present disclosure, there are provided at least the following structure and methods:

(1) A charging current acquiring device, which is configured for acquiring a charging current of a display zone thin film transistor of a display device, and includes a detecting thin film transistor with the same construction as the display zone thin film transistor.

(2) The charging current acquiring device according to (1), wherein, a first scan signal is input to a gate electrode of the display zone thin film transistor, a first data signal is input to its source electrode; a second scan signal being the same as the first scan signal is input to a gate electrode of the detecting thin film transistor, a second data signal is input to its source electrode; and the acquired charging current is output from a drain electrode of the detecting thin film transistor.

(3) The charging current acquiring device according to (2), wherein, the second data signal is the same as the first data signal; or, the second data signal is the same as a data signal in correspondence with the display zone thin film transistor at a selected gray scale.

(4) The charging current acquiring device according to (3), wherein, the selected gray scale is the highest display gray scale of the display device.

(5) The charging current acquiring device according to any of (1) to (4), wherein, the display device includes an array substrate, and the charging current acquiring device is formed on the array substrate.

(6) The charging current acquiring device according to (5), wherein, the display device further includes a driving circuit board that is formed on the array substrate; a gate electrode, a source electrode and a drain electrode of the detecting thin film transistor are connected to the driving circuit board through connecting lines, respectively.

(7) The charging current acquiring device according to (5), wherein, the display device further includes a driving circuit board that is connected to the array substrate through a flexible circuit board; a gate electrode, a source electrode and a drain electrode of the detecting thin film transistor are connected to the flexible circuit board through connecting lines, respectively.

(8) A display device driving device, comprising a timing controller, a driving circuit board connected to the timing controller and the charging current acquiring device according to any of (1) to (7).

(9) A driving method of the display device, comprising:

acquiring a charging current of the current display zone thin film transistor at a specific data signal voltage by the charging current acquiring device according to any of (1) to (7);

comparing the acquired charging current value with a preset charging current value;

in case that the acquired charging current value is smaller than the preset charging current value, adjusting the current scan signal voltage or data signal voltage by the timing controller and/or the driving circuit board.

(10) An array substrate, comprising the charging current acquiring device according to any of (1) to (7).

(11) A manufacturing method of an array substrate, comprising:

forming a display zone thin film transistor and a detecting thin film transistor with the same construction as the display zone thin film transistor.

(12) The manufacturing method of the array substrate according to (11), wherein, the detecting thin film transistor and the display zone thin film transistor are formed simultaneously.

(13) The manufacturing method of the array substrate according to (12), further comprising:

forming gate electrodes for the display zone thin film transistor and the detecting thin film transistor and connecting lines on a base substrate;

forming a gate insulating layer that covers the whole base substrate on the gate electrodes and the connecting lines;

forming an active layer on the gate insulating layer;

forming source electrodes and drain electrodes for the display zone thin film transistor and the detecting thin film transistor on the active layer;

forming connecting via holes over the connecting lines, so that the source electrode and the drain electrode of the detecting thin film transistor are connected to the connecting lines through the connecting via holes, respectively.

Descriptions made above are merely exemplary embodiments of the invention, but are not used to limit the protection scope of the invention. The protection scope of the invention is determined by attached claims.

This application claims the benefit of priority from Chinese patent application No. 201310557864.9, filed on Nov. 11, 2013, the disclosure of which is incorporated herein in its entirety by reference as a part of the present application.

1. A display device, comprising:
an array substrate, including a display zone thin film transistor situated in a display zone; and
a driving device, including a charging current acquiring device, which is configured for acquiring a charging current of the display zone thin film transistor, and includes a detecting thin film transistor with the same construction as the display zone thin film transistor.

2. The display device according to claim 1, wherein, a first scan signal is input to a gate electrode of the display zone thin film transistor, a first data signal is input to its source electrode; a second scan signal being the same as the first scan signal is input to a gate electrode of the detecting thin film transistor, and a second data signal is input to its source electrode; and the acquired charging current is output from a drain electrode of the detecting thin film transistor.

3. The display device according to claim 2, wherein, the second data signal is the same as the first data signal; or, the second data signal is the same as a data signal in correspondence with the display zone thin film transistor at a selected gray scale.

4. The display device according to claim 3, wherein, the selected gray scale is the highest display gray scale of the display device.

5. The display device according to claim 1, wherein, the charging current acquiring device is formed on the array substrate.

6. The display device according to claim 5, wherein, the driving device further includes a driving circuit board that is formed on the array substrate; and a gate electrode, a source electrode and a drain electrode of the detecting thin film transistor are connected to the driving circuit board through connecting lines, respectively.

7. The display device according to claim 5, wherein, the driving device further includes a driving circuit board that is connected to the array substrate via a flexible circuit board; and a gate electrode, a source electrode and a drain electrode of the detecting thin film transistor are connected to the flexible circuit board through connecting lines, respectively.

8. The display device according to claim 5, wherein, the driving device further includes a timing controller.

9. The display device according to claim 5, wherein, the charging current acquiring device is arranged in a peripheral zone of the array substrate surrounding the display zone.

10. A driving method of a display device comprising an array substrate, including a display zone thin film transistor situated in a display zone; a driving device, including a charging current acquiring device, which is configured for acquiring a charging current of the display zone thin film transistor, and includes a detecting thin film transistor with the same construction as the display zone thin film transistor, a driving circuit board and a timing controller, the method comprising:
acquiring a charging current of the display zone thin film transistor at a specific data signal voltage by the charging current acquiring device;
comparing the acquired charging current value with a preset charging current value;
in case that the acquired charging current value is smaller than the preset charging current value, adjusting a scan signal voltage or the data signal voltage by the timing controller and/or the driving circuit board.

11. A manufacturing method of an array substrate, comprising:
forming a display zone thin film transistor and a detecting thin film transistor with the same construction as the display zone thin film transistor.

12. The manufacturing method of the array substrate according to claim 11, wherein, the detecting thin film transistor and the display zone thin film transistor are formed simultaneously.

13. The manufacturing method of the array substrate according to claim 12, further comprising:
forming gate electrodes for the display zone thin film transistor and the detecting thin film transistor and connecting lines on a base substrate;
forming a gate insulating layer on the gate electrodes and the connecting lines to cover the whole base substrate;
forming an active layer on the gate insulating layer;
forming source electrodes and drain electrodes for the display zone thin film transistor and the detecting thin film transistor on the active layer; and
forming connecting via holes over the connecting lines, so that the source electrode and the drain electrode of the detecting thin film transistor are connected to the connecting lines through the connecting via holes, respectively.

14. The display device according to claim 2, wherein, the charging current acquiring device is formed on the array substrate.

15. The display device according to claim 3, wherein, the charging current acquiring device is formed on the array substrate.

16. The display device according to claim 4, wherein, the charging current acquiring device is formed on the array substrate.
